(19) United States
(12) Patent Application Publication
(10) Pub. No.: US 2007/0092740 A1
(43) Pub. Date: Apr. 26, 2007

(54) Metal coatings

(75) Inventors: Xu Shi, Singapore (SG); Li Kang Cheah, Singapore (SG)

Correspondence Address: KING & SPALDING LLP, 1180 PEACHTREE STREET, ATLANTA, GA, 30309-3521, US

(73) Assignee: Nanofilm Technologies International Pte Ltd., Singapore (SG)

(21) Appl. No.: 11/500,608

(22) Filed: Aug. 8, 2006

Related U.S. Application Data
(60) Provisional application No. 60/706,367, filed on Aug. 8, 2005.

(51) Int. Cl. C23C 16/00; H05H 1/24; B32B 15/04

(52) U.S. Cl. 428/457; 427/569; 427/248.1; 428/469

(57) ABSTRACT

A method of forming a metal coating comprising the steps of: (a) generating an arc at a metal target to create metal ions in a chamber that is under vacuum or has an inert atmosphere; (b) depositing the metal ions on a substrate to form a metal layer thereon; and (c) controlling an amount of gas in the chamber to form a primary metal-gas compound layer on said metal layer and a secondary metal-gas compound layer on said primary metal-gas compound layer, wherein said primary and secondary metal-gas compound layers have different gas atom contents.

### TECHNICAL FIELD

The present invention generally relates to a method of making metal coatings. In particular, the invention relates to thin film metal coatings, methods of making the thin film metal coatings and to uses and applications of the coatings.

### BACKGROUND

It is well known to manufacture polymers and other plastic articles by allowing a heated polymer or plastic liquid phase material to cool in a mould so that the formed articles assume the shape of the mould. Very generally, moulds for plastic articles are made typically of heat-treated steel. The mould surfaces are treated with various coatings to ensure that an article can be successfully released after formation in the mould. One known coating is titanium nitride.

In the moulding of epoxy-based polymers, it is known that such polymers tend to stick to mould surfaces more avidly than other polymers. To reduce this sticking, it Is known to coat mould surfaces with a thin layer of chrome. This layer is deposited typically using electroplating technology and is sometimes referred to as a “hard chrome” layer.

Ideally, the hard chrome layer should be laid down thinly and evenly over the surface of a substrate. However, a known problem with the existing hard chrome coating technique is that the coating is uneven and does not evenly coat all of the projections, flat surfaces and pits in the substrate profile. This is a particular problem where the substrate is being used as a mould.

It is believed that the uneven coating arises from electrical field effects that occur at corners and junctions of the substrate surface. These electrical field effects are believed to result in a larger deposition of coating at the corners and junctions of the substrate surfaces relative to the planar surfaces of the substrate. One way to alleviate this problem is to redesign the shape of the mould so that an uneven deposition does not result in moulding difficulties, for example due to overhangs. However, any specific redesign of the mould to take account of electroplating problems is undesirable as it is time consuming and difficult.

Another known problem with the hard chrome layer is that whilst it is less sticky than other coatings, it would nevertheless be desirable for the coating to be even less sticky with respect to the polymer being molded. Additionally, the electroplating process tends to produce a chrome layer which contains micro-cavities. The resulting density of the layer is generally around 70-80% of the density of bulk chrome. It would be desirable for this density to be increased, giving an intact, smoother coating.

The hardness of the electroplated hard chrome layer is typically between 8 and 10 GPa. For many applications increased hardness is desired.

Sputter coating techniques can also be used to deposit chrome coatings on moulds, but again these tend to give uneven, low density coatings that initially or in time become unacceptably sticky resulting in difficulties in releasing articles from the mould.

It would be an advantage if embodiments of the invention overcame, or at least ameliorated, one or more of the above problems.

### SUMMARY

A first aspect provides a method of forming a metal coating comprising the steps of:
(a) generating an arc at a metal target to create metal ions in a chamber that is substantially under vacuum or has a substantially inert atmosphere;
(b) depositing the metal ions on a substrate to form a metal layer thereon; and
(c) controlling an amount of gas in the chamber to form a primary metal-gas compound layer on said metal layer and a secondary metal-gas compound layer on said primary metal-gas compound layer, wherein said primary and secondary metal-gas compound layers have different gas atom contents.

In one embodiment, there is provided a method of forming a chrome nitride coating comprising the steps of:
(a) generating an arc at a chrome metal target to create chrome ions in a chamber that is substantially under vacuum or has a substantially inert atmosphere;
(b) depositing the chrome ions on a substrate to form a chrome metal layer thereon; and
(c) controlling an amount of nitrogen in the chamber to form a primary chrome nitride layer on said chrome metal layer and a secondary chrome nitride layer on said primary chrome nitride layer, wherein said primary and secondary chrome nitride layers have different nitrogen contents.

A second aspect provides a coated substrate comprising:
a substrate;
a metal layer provided on the substrate; and
a primary metal-gas compound layer on said metal layer;
a secondary metal-gas compound layer on said primary metal-gas compound layer, said secondary metal-gas compound layer having a different gas atom content relative to said first metal-gas compound layer.

In one embodiment, there is provided a coated substrate comprising:
a substrate;
a chrome layer provided on the substrate; and
a primary chrome nitride layer on said chrome layer;
a secondary chrome nitride layer on said primary chrome nitride layer, said secondary chrome nitride layer having a different nitrogen content relative to said primary chrome nitride layer. In one embodiment, the nitrogen content of the primary chrome layer is less than the nitrogen content of the secondary chrome nitride layer.

A third aspect provides a multi-coated substrate comprising:
a substrate;
a metal layer provided on the substrate; and
a plurality of metal-gas compound layers provided on said metal layer; at least two of said plurality of metal-gas compound layers having different gas atom contents.

A fourth aspect provides a multi-coated substrate formed in a Filtered Cathodic Vacuum Arc process comprising:
a substrate;
a metal layer provided on the substrate; and
a plurality of metal-gas compound layers provided on said metal layer; at least two of said plurality of metal-gas compound layers having different gas atom contents.

A fifth aspect provides a multi-coating for a substrate comprising:
a metal layer; and
a primary metal-gas compound layer on said metal layer; and
a secondary metal-gas compound layer on said primary metal-gas compound layer, said secondary metal-gas compound layer having a different gas atom content relative to said first metal-gas compound layer.

A sixth aspect provides a coating for a substrate comprising:
a metal layer;
a primary metal-gas compound layer on said metal layer; and
a secondary metal-gas compound layer on said primary metal-gas compound layer, said secondary metal-gas compound layer having a different gas atom content relative to said first metal-gas compound layer.

A seventh aspect provides a substrate coated with a coating made in a method according to the first aspect.

An eighth aspect provides mould coated with a coating, said coating comprising:
a metal layer;
a primary metal-gas compound layer on said metal layer; and
a secondary metal-gas compound layer on said primary metal-gas compound layer, said secondary metal-gas compound layer having a different gas atom content relative to said first metal-gas compound layer.

An ninth aspect provides mould coated with a multi-coat coating, said multi-coat coating comprising:
a metal layer;
a plurality of metal-gas compound layers provided on said metal layer, wherein at least two of said plurality of metal-gas compound layers having different gas atom contents relative to each other.

### Definitions

The following words and terms used herein shall have the meaning indicated:

As used herein, the term “metal-gas compound” and grammatical variations thereof, is intended to refer to a compound comprising a metal atom and a gas atom. The metal atom may be bonded directly to the gas atom or indirectly via another atom. The metal-gas compound may comprise more than one metal atom and more than one gas atom.

As used herein, the term “gas atom” and grammatical variations thereof, is intended to refer to atoms that are in a gaseous phase when in their atomic or molecular form at 25° C. and 101.3 kPa. Exemplary gas atoms include nitrogen (N) which is in a gaseous phase in its molecular form (N₂) at 25° C. and 101.3 kPa.

As used herein, the term “gas atom content” and grammatical variations thereof, is intended to refers to the number of gas atoms relative to the total number of atoms in a metal-gas compound.

As used herein, the term “stoichiometric metal-gas compounds” and grammatical variations thereof, is intended to refer to metal-gas compounds having a gas atom content that is the maximum amount of gas atoms that could theoretically react with a given amount of metal atoms employed. For example, if a reaction between chrome (Cr) and nitrogen gas (N₂) is as follows:
Cr(s)+½N₂→CrN(s) (1)
the compound CrN formed in (1) is the stoichiometric metal compound at thermodynamic equilibrium in which the stoichiometric nitrogen atom content relative to one atom of Cr is one.

Unless specified otherwise, the terms “comprising” and “comprise”, and grammatical variants thereof, are intended to represent “open” or “inclusive” language such that they include recited elements but also permit inclusion of additional, unrecited elements.

### DETAILED DISCLOSURE OF EMBODIMENTS

Exemplary, non-limiting embodiments of a metal coating method and a metal coated substrate will now be disclosed. The disclosed embodiments relate to coatings, methods of depositing coatings, and to uses thereof, based on an interleaved structure of metal and metal-gas compound layers. The disclosed embodiments also relate to deposition of metal-gas compound layers using Filtered Cathodic Vacum Arc (FCVA) technology and to combinations thereof.

The gas may comprise one or more atoms selected from the group consisting of nitrogen (N), oxygen (O), hydrogen (H), sulfur (S) and mixtures of thereof. The gas may be in the form of a pure gas such as pure nitrogen (N₂), hydrogen (H₂) or oxygen (O₂) or alternatively, it may comprise molecules of the gas atoms. Exemplary molecules of the gas atoms include ammonia, nitrogen oxides, sulfur oxides, nitrous oxides, and hydrogen sulfides.

Preferably, the metal-gas compound is a compound of the metal and one or more atoms of the gas. In one embodiment, the gas is nitrogen and the metal compound is a metal nitride. In other embodiments, the metal compounds are selected from the group consisting of metal oxides, metal sulfides and metal hydrides.

Advantageously, the gas atom content of the primary metal-gas compound layer being different to the gas atom content of the secondary metal-gas compound layer results in reduced stress between the two layers. Advantageously, as the primary and secondary metal-gas compound layers preferably have a gas atom content less than a layer of stoichiometric metal-gas compounds, said primary and secondary layers have at least one of reduced stickiness, improved hardness relative to a layer of stoichiometric metal-gas compounds. The primary and secondary metal-gas compound layers may also allow superior binding to other metal or metal compound coatings, such as a stoichiometric chromium nitride.

In one embodiment, the method may further comprise the step of depositing a metal compound having a substantially stoichiometric ratio of gas atoms relative to metal atoms on the metal-gas compound layer.

In one embodiment, the coating on a substrate comprises four alternating layers: (a) a metal layer formed on the substrate, (b) a primary metal-gas compound layer formed on the metal layer; and (c) a secondary metal-gas compound layer formed on the primary metal-gas compound layer, wherein the gas atom content of the primary and secondary layers are different. Optionally, in one embodiment, the metal-gas compounds of the secondary layer are stoichiometric metal-gas compounds while the primary metal-gas compound layer has a gas content less than the secondary metal-gas compounds. In one embodiment, the method may further comprise depositing layers of a further metal-gas compound, different to (b), thereon. If the first metal compound is, say, a metal nitride the second can be, say, a metal oxide.

In another embodiment, there is provided a method of providing a coating on a substrate, comprising depositing a plurality of layers of metal interleaved with a one or more layers of metal-gas compounds. Again, layers of a further compound can optionally be interleaved with the metal and metal-gas compounds.

Coatings of the specific embodiments may be deposited using FCVA and hence the metal can be any metal that is a target in the FCVA. In one embodiment, the metal may be selected from the group consisting of group IIIB, group IVA and group VIA of the Periodic Table of Elements and alloys thereof. Exemplary metals are chrome (Cr), titanium (Ti), Tantalum (Ta), aluminium (Al) and zirconium (Zr).

FCVA coatings are laid down in a vacuum chamber and hence the gas is introduced to make the metal compound layer and then removed, e.g. by the continued evacuation of the chamber. As a result the metal layers are generally not pure, as there is residual gas left in the chamber during their deposition, leading to a gas content in the metal layer of 3% or less by number of atoms. Preferably the gas content is 2% or less. The metal layers are at least 97% pure, preferably at least 98% pure, more preferably 99% or higher.

The gas atom deficiency of the metal-gas compounds is produced by controlling the amount of gas within the vacuum chamber.

Generally, the overall composition of the metal-gas compound layers may be represented by the general formula:
MₓG_{y}

wherein M represents one or more metal atoms in the metal compound layer, G represents one or more gas atoms metal compound layer, wherein x represents the fraction of metal atoms metal compound layer, y represents the fraction of gas atoms metal compound layer and x+y=1.

In one embodiment, y has a value selected from the group consisting of 0.08 to 0.35, 0.08 to 0.30, 0.08 to 0.25, 0.08 to 0.2, 0.08 to 0.18, 0.08 to 0.16, 0.08 to 0.15, 0.08 to 0.14, 0.08 to 0.13, 0.08 to 0.12, and 0.08 to 0.11. In one embodiment, x is a value selected from the group consisting of 0.92 to 0.65, 0.92 to 0.7, 0.92 to 0.75, 0.92 to 0.8, 0.92 to 0.82, 0.92 to 0.84, 0.92 to 0.85, 0.92 to 0.86. 0.92 to 0.87, 0.92 to 0.88 and 0.92 to 0.89.

In one embodiment, the weight percentage of gas atoms in the metal gas compound is selected from the group consisting of 2% to 13%, 2% to 12%, 2% to 10%, 2% to 8%, 2% to 6%, 2% to 4%, 4% to 13%, 6% to 13%, 8% to 13%, 10% to 13%, and 12% to 13%, the remainder being substantially metal atoms.

In one embodiment, M is chromium (Cr), G is nitrogen (N) as follows CrₓN_{y}. It will be appreciated that for the stoichiometric thermodynamic equilibrium compound CrN, all of the above disclosed ranges are nitrogen-deficient because the stoichiometric thermodynamic equilibrium amount of x and y for CrN are x=0.5 and y=0.5. In another embodiment, the stoichiometric thermodynamic equilibrium compound Cr₂N, the above disclosed ranges will be nitrogen-deficient for x being less than ⅔ and y being less than ⅓. Other exemplary metal-gas compounds include: (a) TiₓN_{y}, which is gas-atom-deficient relative to TiN; (b) (TiAl)ₓN_{y}, which is gas-atom-deficient relative to (TiAl)N; (c) TaₓN_{y}, which is gas-atom-deficient relative to TaN; and (d) TiₓO_{y}, which is gas-atom-deficient relative to TiO₂.

Coatings of the disclosed embodiments have been deposited onto steel substrates, e.g. the hard steel used for disk moulds, and have been found to exhibit improved hardness and improved stickiness (i.e. have reduced stickiness) when compared to electroplated chrome coatings. The combination of both metal and metal-gas compound layers enables these properties to be obtained. Whilst not wishing to be bound by theory, it is believed that the respective metal and metal-gas compound layers are sufficiently thin for the coating effectively to comprise a lattice of metal layers and a lattice of metal-gas compound, the resultant combined lattices giving the improved properties as described herein. In both hardness and anti-stick tests, a chrome/chrome nitride coating made in an example below compared favorably with a known electroplated hard chrome mould coating.

The known hard chrome coating is normally about 3 microns in depth, but coatings of the invention are advantageously found to be dense and even, and can be thinner than this, providing improved hardness and anti-stick even when just 1 micron thick. The layers of the coating of the invention typically have, independently, thickness in the range of 0.3-6 nm (3-60 angstroms), especially in the range of 0.5-4 nm (5-40 angstroms), more preferably 0.8-25 nm (8-25 angstroms). The chrome/chrome nitride coating of an example has chrome layers of about 1 nm (10 angstroms) and chrome nitride layers of about 2 nm (20 angstroms).

The production method used in the method of the examples results in metal:metal-gas compound thickness ratios, typically 0.8:2, 0.8:1.8, 0.8:1.5, 0.8:1.4, 0.8:1.2, 0.8:1.1, 0.8:1, 1:1, 2:0.8, 1.8:0.8, 1.6:0.8, 1.4:0.8, and 1.2:0.8, e.g. 8 nm:20 nm, 8 nm:18 nm, 8 nm:15 nm, 8 nm:14 nm, 8 nm:12 nm, 8 nm:11 nm, 8 nm:10 nm, 20 nm:8 nm, 18 nm:8 nm, 16 nm:8 nm, 14 nm:8 nm, 12 nm:8 nm, though with different production these ratios can vary.

The gas may be introduced into the chamber intermittently or constantly during deposition of the metal ions on the metal target. The amount of gas introduced into the chamber may be controlled by varying the partial pressure of the gas in the vacuum chamber. The partial pressure of the gas in the vacuum chamber during deposition of the metal ions on the metal target may be in the range selected from the group consisting of 0.5-5×10⁻⁴ torr (˜0.0067-0.067 Pa), 0.82×10⁻⁴ torr (˜0.01-0.027 Pa), 1-2×10⁻⁴ torr (˜0.013-0.027 Pa), 1.1-1.8×10⁻⁴ torr (˜0.0146-0.024 Pa), 1.2-1.6×10⁻⁴ torr (˜0.016-0.02 Pa).

A still further, more specifically disclosed embodiment, is a method of depositing a metal nitride coating on a substrate, comprising generating an arc at a metal target in a vacuum chamber, thereby creating metal ions, and depositing the metal ions on the metal target in the presence of nitrogen, wherein the partial pressure of nitrogen in the chamber is controlled so that the metal nitride coating contains from 8-35% nitrogen by atom number.

These embodiments used FCVA methods, which are preferred for all coatings, and a preferred coating comprises chrome, made using a chrome target.

Stress can build up in these sorts of coatings, and it is optional to bias the substrate to reduce the stress in the coating. Suitably, the methods comprises biasing the substrate at a voltage in the range selected from the group consisting of −600V to −4,000V,

Compositions and coated substrates per se also form aspects of the invention. Thus, the invention lies also in a coated substrate obtained according to any of the methods of the invention.

A particular composition of the invention comprises a plurality of layers of chrome alternating with or interleaved with a plurality of layers of nitrogen-deficient chrome nitride, wherein the thickness of each layer is independently in the range 0.3-5 nm (3-50 angstroms).

Tests of the composition, e.g. when coated onto a hard steel substrate, demonstrate that the coating has a hardness of at least 15 GPa and a friction co-efficient of 0.4 or less. Hardness of up to 20 GPa has also been recorded for specific chrome-based coatings. A further embodiment of the invention comprises a plurality of alternating or interleaved layers of (a) metal, and (b) at least two metal-gas compound layers having different gas atom contents.

The composition may be layered, generally multi-layered, and the thickness of the layers may be independently in the range 0.3-5 nm (3-50 angstroms).

Using FCVA deposition methods highly dense coatings of chrome/nitrogen-deficient chrome nitride are produced. Hence a still further disclosed embodiment is a substrate comprising a metal nitride coating, wherein the density of the coating is at least 90% of the density of the bulk metal nitride, preferably at least 95%, preferably at least 98%, preferably at least 99%. Coatings deposited and tested have been found to have substantially 100% of the theoretical density of the bulk material. This high density indicates few or even substantially no micro-cavities in the coating, thus indicating a flat, non-sticky coating has been deposited. A specific coating results in a substrate comprising a chrome nitride coating, wherein the coating has a hardness of 15 GPa or greater, a friction co-efficient of 0.40 or less and a water contact angle of 90° or higher.

A particular application for these coatings is the moulding of semiconductor devices, and hence a specific article made by the invention is a mould for moulding polymers, coated with any composition of the invention.

An FCVA apparatus used to deposit the disclosed coatings may include a heater in the deposition chamber. The heater can be used to drive away moisture from the mould. An ion-beam source may also be used to clean and activate substrate surfaces prior to deposition.

Prior to depositing a coating, a seed layer can be deposited on to the substrate. Typically, the seed layer is the same metal as used for the coating and thus for a chrome/nitrogen-deficient chrome nitride coating, the seed layer is chrome and can have a depth of from 10-200 nm (100-2,000 angstroms), often about 100 nm (1,000 angstroms). On top of this seed layer, a coating is deposited so that the total depth is 5 microns or less, preferably 2 microns or less.

In one embodiment, a disclosed coating may have a seed layer of 10-200 nm, a coating of 200 nm-2,000 nm and then, optionally, a top layer of 100 nm-1,000 nm. This top layer is typically a stoichiometric chrome nitride layer.

In one embodiment, the coating has: (a) bottom layer of chrome metal; (b) an intermediate layer comprising a primary chrome nitride layer having a low nitrogen content between about 5% to about 15% by atom number and a secondary chrome nitride layer on said primary layer having a high nitrogen content between about 15% to about 25% by atom number, and optionally (c) a layer of stoichiometric CrN.

### Properties

The disclosed coatings have been found to have a water contact angle of approximately 95 degrees (one sample was specifically measured as 94.82 degrees), indicating that the coatings exhibit relatively hydrophobic, non-sticky properties. By comparison, the water contact angle for Teflon is about 120 degrees, whereas the water contact angle for known hard chrome coatings are about 75 degrees (typically in the range of 70-80).

The coatings generally have a lower wear rate than those in the art, indicating they are harder as measured by a scratch test. The disclosed coatings have a wear rate of about 10⁻⁷ mm³/Nm, which compares favorably with a typical value of 10⁻⁵ mm³/Nm for known hard chrome coatings.

In anti-sticking tests, the coatings have been found to have a value of about 0.3, hard chrome being normalized to a value of 1. This indicates reduced stickiness compared to the existing coatings. One suitable anti-sticking test comprises moulding a polymer onto a mould surface coated with the test coating. An ejector pin is then used to eject the article from the mould, the force required to eject the article being measured and normalized according to the benchmark surface (eg. hard chrome). A value of less than 1 for a coating of the disclosed embodiments thus indicates improved anti-stick properties.

### Biasing

In a specific embodiment, described in more detail below, deposition of the metal layers is carried out using a bias of the substrate of around −1500 volts, pulsed at 2 kHz for 20 microseconds per pulse. This biasing can, however, be varied. An advantage of applying a biasing the substrate is that it has been found that the resultant coating exhibits reduced stress when subjected to an external force compared to coatings that are prepared without biasing.

Biasing is not necessary to lay down the coating but a preferred method employs a bias pulse to a value in the range selected from the group consisting of −300V to 4000V, −300V to −3000V, −300V to −2500V, −300V to −2000V, −300V to −1500V, −300V to −1000V, −500V to 4000V, −1000V to 4000V, −1500V to −4000V, −2000V to −4000V, −2500V to −4000V, and −3000V to −4000V. In one particular embodiment, the bias pulse between −800V to −3000V.

Also in the specific embodiment described below in more detail, deposition of the metal nitride-containing layer is carried out with a bias of approximately −2400V, pulsed at 2 kHz for 20 microseconds each pulse. This bias can also vary. The bias is preferably pulsed at between −500 and −5000V, preferably between −1000 and −4000V.

The frequency and pulse duration of the pulsed biasing can also vary. The frequency is typically between 0.5 and 10kHz and the pulse duration is typically between 2 and 50 microseconds.

### BRIEF DESCRIPTION OF DRAWINGS

The accompanying drawings illustrate a disclosed embodiment and serve to explain the principles of the disclosed embodiment. It is to be understood, however, that the drawings are designed for purposes of illustration only, and not as a definition of the limits of the invention.

FIG. 1 is a schematic diagram of a FCVA apparatus used to coat a substrate in accordance with a disclosed embodiment;

FIG. 2 shows a chrome nitride coating formed in a disclosed method or a hard chrome coating of the prior art being attached to a polymer substrate being formed in a mould in an anti-sticking test apparatus;

FIG. 3 shows the chrome nitride coating formed in the disclosed method or the hard chrome coating of the prior art attached to the polymer substrate after being removed from the mould of FIG. 4 in an anti-sticking test apparatus; and

FIG. 4 shows an exemplary embodiment of a multi-coating formed in another disclosed embodiment.

### EXAMPLE 1

### Coating

An FCVA apparatus as described in U.S. Pat. No. 6,031,239 and EP 0811237, the full disclosures of which are incorporated herein, was used to deposit a chrome/nitrogen deficient chrome nitride coating onto substrates mounted on a rotating carousel in a deposition chamber.

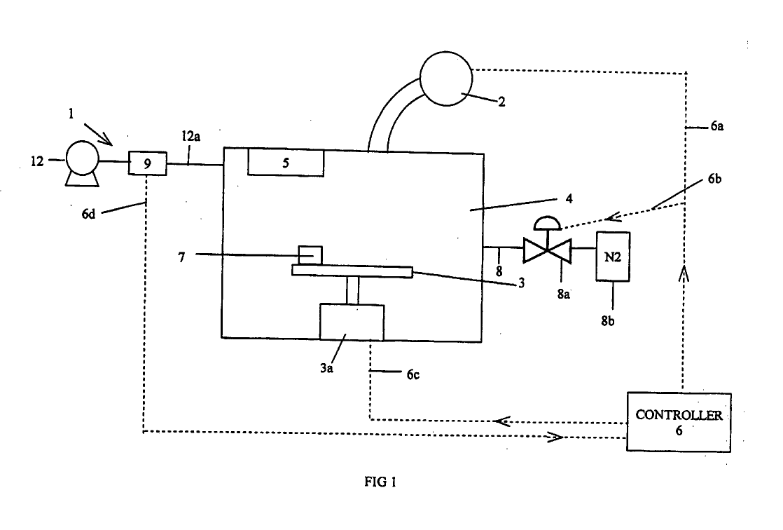

Referring to FIG. 1, an apparatus used to make the invention is shown schematically as 1 and comprises a filtered cathode vacuum arc 2 arranged to deposit ions onto substrates on rotating substrate holder 3 in deposition chamber 4, the chamber being a continuation of the vacuum chamber of the FCVA 2. The substrate holder 3 is driven by motor 3a. A heater 5 is located in the deposition chamber 4 for heating substrates e.g. to drive away moisture prior to deposition. A nitrogen feed line 8 feeds nitrogen into the chamber from nitrogen tank 8b via control valve 8a. A system controller 6 controls operation of (i) the FCVA 2 (as shown by dashed line 6a); the control valve 8a (as shown by dashed line 6b); the motor 3a for rotating the substrate holder and the biasing unit 7 (as shown by dashed line 6c). An emission monitor 9 provided on conduit 12a monitors the gas output from the chamber 4 to determine the level of nitrogen gas therein and thereby allow the controller 6 to adjust the control valve 8a. A pump 12 provided on conduit 12a provides a vacuum within the chamber 4 and is also controlled by the controller.

In this set-up, the ratio of the thickness of the respective metal and metal compound layer was an integer, as the substrate holder rotated at a constant speed. In the coating tested, chrome:chrome nitride compound layers were deposited in the ratio 1:2,though this ratio can vary.

During deposition, the FCVA and the deposition chamber were continually evacuated and hence introduction of nitrogen into the chamber controlled the partial pressure of nitrogen and the resultant nitrogen content of the nitride layers. The controller 6 operated as a mass flow controller calibrated in standard cubic centimeter per minute, SCCM units. In use, nitrogen was introduced at 6 SCCM, resulting in a partial pressure of about 1×10⁻⁴ torr (˜1.33×10⁻² Pa), and whilst this is in theory an excess of nitrogen, as only a proportion of the nitrogen reacts with the metal ions, a chrome nitride layer having a nitrogen content less than stoichiometric nitrogen was produced.

The FCVA was operated using a chrome target at a high direct current in the range 100 A-180 A, preferably 140 A-180 A. The target was 70 mm in diameter and the ducting of the FCVA between the target and the deposition chamber was 200 mm in diameter. The carousel was 700 mm in diameter, rotating at 0.83 rpm (50 seconds per revolution). The FCVA was operated alternately for 50 seconds to deposit the chrome-containing layer (thickness about 1 nm) and 100 seconds to deposit the chrome nitrde-containing layer (thickness about 2 nm). During deposition of the metal layers, the substrate was biased at −1500 volts, pulsed at 2 kHz for 20 microseconds per pulse.

An initial seed layer of chrome was deposited having thickness of approximately 100 nm (1,000 angstrom). After this, nitrogen was introduced into the vacuum chamber at a controlled rate whilst depositing the primary chrome nitride layer having a nitrogen content less than a stoichiometric amount of CrN. The vacuum pump was operated to produce a vacuum of approximately 10⁻⁶ torr (˜1.33×10⁻⁴ Pa), operating continuously to incorporate a very small amount of nitrogen, estimated at about 1%, was into the chrome layer. The primary chrome nitride layer had a nitrogen content of about 12% (ie Cr_{0.88}N_{0.12}).

After formation of the primary chrome nitride layer, the vacuum was reduced to allow more nitrogen to enter the chamber, estimated at about 1.5%, and thereby incorporate the nitrogen into the chrome layer. The secondary chrome nitride layer had a nitrogen content of about 17% (ie Cr_{0.83}N_{0.17}). Accordingly, the nitrogen content of the secondary chrome layer was higher than that of the primary chrome layer and both of the formed primary and secondary chrome layers were nitrogen deficient with respect to stoichiometric CrN.

For deposition of the alternate chrome layers, the introduction of nitrogen was stopped, the partial pressure of nitrogen dropping rapidly to 0.01 mtorr (˜1.33 mPa) or below.

The plasma exiting the duct of the FCVA was scanned at 30 Hz to a diameter of about 10 cm and deposition was continued for a period of three hours, resulting in a coating thickness of approximately 0.8 microns, corresponding to a deposition rate of about 1 angstrom per second. A top layer of 300 nm of nitrogen-deficient chrome nitride was then deposited over the multi-layer coating.

The coating was found to have the following properties:

| | |
|---|---|
| Thickness | 1 micron |
| Water Contact Angle | 94.82 degrees |
| Wear Rate | 10−⁷ mm³/Nm |
| Co-Efficient of Friction | 0.20 |
| Hardness | 20 GPa |
| Anti-Sticking Test | 0.3 (in the test, the value for hard chrome is |
| | normalised to 1). |

### Anti-Sticking Test

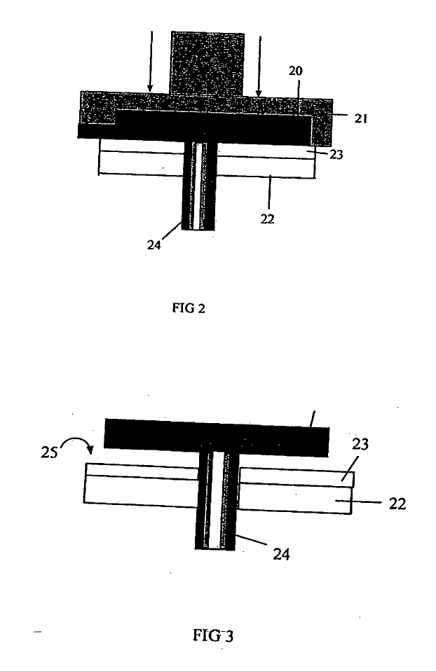

Referring to FIGS. 2 and 3, an epoxy-containing polymer 20 was moulded in a mould 21 against a steel surface 22 coated with (1) a coating prepared according to the example as described above, or (2) a hard chrome coating of the art 23. The steel surface was in the form of a disk with a central ejector pin 24, the end of the pin being substantially level with the top 25 of the coating. After moulding, the upper mould member was removed (refer to FIG. 3), leaving the moulded article lying on or adhered to the coated steel disk. The force required on the ejector pin to eject the moulded article from the surface was measured, the value required to eject from the hard chrome surface being normalised to 1. Using this test, the coating of the invention had a value of ⅓, indicating that the coating had reduced stickiness relative to a hard chrome coating.

### EXAMPLE 2

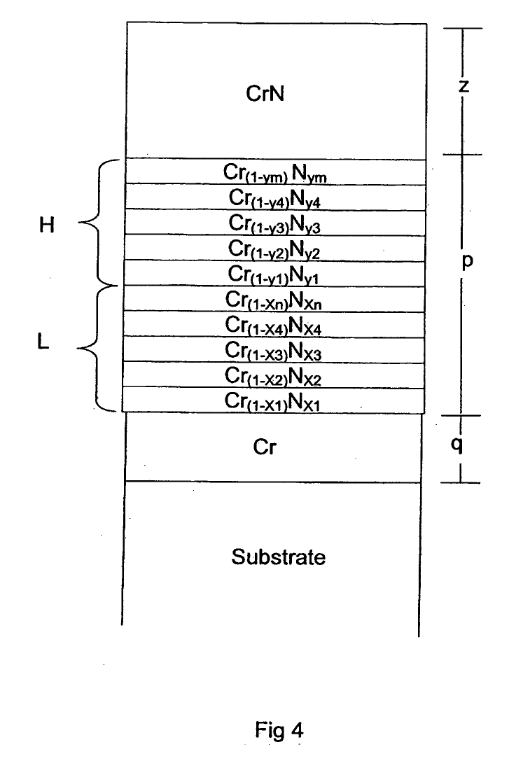

Another coating was formed in the apparatus and under the same conditions as Example 1 except that in this example a plurality chrome nitride compound layers having a nitrogen content less than stoichiometric CrN were successively layered on Cr metal. Referring to FIG. 4, the coating consists of (a) bottom layer (q) of chrome (Cr) metal; (b) an intermediate layer comprising a plurality of chrome nitride layers having a nitrogen content less than stoichiometric chrome nitride (CrN); and (c) a stoichiometric chrome nitride (CrN) top layer.

The bottom layer q of Cr was deposited under a vacuum on a metal substrate to form a 0.1 μm layer.

The intermediate layer P comprised a low nitrogen sub-layer (L) consisting of a plurality of n layers of chrome nitride having a nitrogen content between about 5% to about 15% by atom number. The layers of sub-layer L were formed successively while increasing the nitrogen content within the chamber 4 from 0.8×10⁻⁴ torr to 1×10⁻⁴ torr (1.066×10⁻² Pa to 1.33×10⁻² Pa) to successively increase the nitrogen content of each layer in the sub-layer (L). The formed layers 1, 2, 3, 4 . . . n of sub-layer (L) were approximately as follows: Cr_{(1-X1)}N_{X1}=Cr_{0.95}N_{0.5}; Cr_{(1-X2)}N_{X2}=Cr_{0.97}N_{0.03}; Cr_{(1-X3)}N_{X3}=Cr_{0.9}N_{0.1}; Cr_{(1-X4)}N_{X4}=Cr_{0.89}N_{0.11}; . . . Cr_{(1-Xn)}N_{Xn}=Cr_{0.85}N_{0.15}. The intermediate layer P also comprised a high nitrogen sublayer (H) consisting of a plurality of m layers of chrome nitride having a nitrogen content between about 15% to about 25% by atom number. The layers of sub-layer H were formed successively while increasing the nitrogen content within the chamber 4 from 1×10⁻⁴ torr to 1.3×10⁻⁴ torr (1.33×10⁻² Pa to 1.73×10⁻² Pa) to successively increase the nitrogen content of each layer in the sub-layer (H). The formed layers 1, 2, 3, 4 . . . m of sub-layer (H) were approximately as follows: Cr_{(1-Y1)}N_{Y1}=Cr_{0.84}N_{0.16}; Cr_{(1-Y2)}N_{Y2}=Cr_{0.82}N_{0.18}; Cr_{(1-Y3)}N_{Y3}=Cr_{0.8}N_{0.2}; Cr_{(1-Y4)}N_{Y4}=Cr_{0.77}N_{0.23}; . . . Cr_{(1-Ym)}N_{Ym}=Cr_{0.75}N_{0.25}.

Each of the layers in sub-layer H and sub-layer L had a thickness of about 0.1 nm, ultimately forming the intermediate layer P having a total thickness of 0.9 microns.

The top layer Z of stoichiometric chrome nitride CrN (Z) had a thickness of 0.5 μm and was formed by increasing the partial nitrogen pressure to above 1.4×10⁻⁴ torr (1.866×10⁻² Pa). Accordingly, the coating had a total thickness of 1.5 μm.

The resulting thin coating exhibited reduced stickiness, good hardness combined with reduced stress in the coating layer.

Coatings of the disclosed embodiments are of particular use in providing a hard, non-sticky coating for metal moulds used to mould plastic materials, especially epoxy-containing plastics. The coatings can, however, be used in a wide number of applications, including moulds for moulding rubbers and a wide variety of other polymers. The coatings can be applied to domestic items such as saucepans and other kitchenware, and can be applied to heating elements such as those found in kettles and other water heaters. The coatings can also be deposited upon glass and plastics, as deposition does not necessarily require the use of a bias on the substrate.

The multi-layer of the metal nitride coatings, having less nitrogen content relative to stoichiometric metal nitrides, produces a coating with reduced stress relative to a coating of stoichiometric metal nitride while having good hardness.

It will be appreciated that the disclosed method provides a useful alternative to known electroplating technology for producing hard chrome layers Furthermore, the disclosed method provides a hard chrome layer that is capable of being laid down thinly and evenly over the surface of a substrate. The disclosed method therefore overcomes the problems associated with existing hard chrome coating techniques that result in uneven coatings and pits in the substrate profile.

It will be appreciated that the disclosed method results in thin film coating that have enhanced hardness over the known electroplating techniques.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A method of forming a metal coating comprising the steps of:
(a) generating an arc at a metal target to create metal ions in a chamber that is substantially under vacuum or has a substantially inert atmosphere;
(b) depositing the metal ions on a substrate to form a metal layer thereon; and
(c) controlling an amount of gas in the chamber to form a primary metal-gas compound layer on said metal layer and a secondary metal-gas compound layer on said primary metal-gas compound layer, wherein said primary and secondary metal gas compound layers have different gas atom contents.

2. A method as claimed in claim 1, comprising the step of:
(d) depositing one or more additional metal-gas compound layers on said secondary metal-gas compound layer.

3. A method as claimed in claim 2, wherein the gas atom content of said one or more additional metal-gas compound layers is different from at least one of said first and said second metal-gas compound layers.

4. A method as claimed in claim 1, wherein the gas atom content of said primary layer is less than the gas atom content of said secondary layer.

5. A method as claimed in claim 1, comprising the step of:
(e) selecting said gas comprising atoms selected from the group consisting of nitrogen (N), oxygen (O), hydrogen (H), sulfur (S) and mixtures thereof.

6. A method as claimed in claim 1, comprising the step of:
(f) selecting gas from the group consisting of nitrogen (N₂), oxygen (O₂), hydrogen (H₂), nitrogen oxides, sulfur oxides, hydrogen sulfides, ammonia (NH₃), and mixtures thereof.

7. A method as claimed in claim 1, comprising the step of:
(g) selecting the metal-gas compound from the group consisting of metal nitrides, metal imides, metal amides, metal oxides, metal hydrides and metal sulfides.

8. A method as claimed in claim 1, comprising the step of:
(h) selecting the metal from the group consisting of group IIIB, group IVA, and group VIA of the Periodic Table of Elements.

9. A method as claimed in claim 8, comprising the step of:
(h1) selecting the metal from the group consisting of Chrome (Cr), Titanium (Ti), Aluminium (Al), Tantalum (Ta) and Zirconium (Zr).

10. A method as claimed in claim 1, wherein the overall composition of at least one of the primary and secondary metal-gas compound layers are represented by the general formula:
MₓG_{y}
wherein,
M represents one or more metal atoms in the metal compound layer;
G represents one or more gas atoms metal compound layer;
x represents the fraction of metal atoms in the metal compound layer;
y represents the fraction of gas atoms in the metal compound layer; and
x+y=1.

11. A method as claimed in claim 10, comprising the step of:
(i) selecting the value of y from the group consisting of 0.08 to 0.35, 0.08 to 0.30, 0.08 to 0.25, 0.08 to 0.2, 0.08 to 0.18, 0.08 to 0.16, 0.08 to.0.15, 0.08 to 0.14, 0.08 to 0.13, 0.08 to 0.12, and 0.08 to 0.11.

12. A method as claimed in claim 10, comprising the step of:
(j) selecting the value of x from the group consisting of 0.92 to 0.65, 0.92 to 0.7, 0.92 to 0.75, 0.92 to 0.8, 0.92 to 0.82, 0.92 to 0.84, 0.92 to 0.85, 0.92 to 0.86, 0.92 to 0.87, 0.92 to 0.88 and 0.92 to 0.89.

13. A method as claimed in claim 10, comprising the step of:
(k) selecting MₓG_{y} from the group consisting of CrₓN_{y}; TiₓN_{y}; (TiAl)ₓN_{y}; TaₓN_{y}; and TiₓO_{y}.

14. A method as claimed in claim 1, wherein at least one of said primary and secondary metal-gas compound layers has a thickness from 0.3 nm to 6 nm (3-60 angstroms).

15. A method as claimed in claim 1, wherein the controlling step (c) comprises the step of:
(c1) controlling the partial pressure of the gas in the vacuum chamber.

16. A method as claimed in claim 15, wherein the controlling step comprises the step of:
(c2) setting the partial pressure of the gas within the vacuum chamber within the range from 0.5×10⁻⁴ torr to 5×10⁻⁴ torr (˜0.0067 Pa to 0.067 Pa).

17. A method as claimed in claim 1, comprising the step of:
(l) biasing the substrate.

18. A method as claimed in claim 17, wherein the biasing step (l) comprises the step of:
(l1) biasing the substrate in the range of 300V to −4000V.

19. A method as claimed in claim 1, comprising the step of:
(m) selecting chrome as the metal; and
(n) selecting chrome nitride as the metal-gas compound.

20. A method as claimed in claim 19, comprising the step of:
(o) selecting the nitrogen gas atom content in the primary layer of chrome nitride from the group consisting of 8% to 35%, 8% to 30%, 9% to 20%, and 8% to 16% by atom number.

21. A coated substrate comprising:
a substrate;
a metal layer provided on the substrate;
a primary metal-gas compound layer on said metal layer; and
a secondary metal-gas compound layer on said primary metal-gas compound layer, said secondary metal-gas compound layer having a different gas atom content relative to said first metal-gas compound layer.

22. A coated substrate as claimed in claim 21, further comprising one or more additional metal-gas compound layers on said secondary metal-gas compound layer.

23. A coated substrate as claimed in claim 22, wherein the gas atom content of said one or more additional metal-gas compound layers is different from at least one of said first and second metal-gas compound layers.

24. A method as claimed in claim 21, wherein the gas atom content of said primary layer is less than the gas atom content of said secondary layer.

25. A coated substrate as claimed in claim 21, wherein the metal-gas compounds comprise gas atoms selected from the group consisting of nitrogen (N), oxygen (O), hydrogen (H), and sulfur (S).

26. A coated substrate as claimed in claim 21, wherein the metal-gas compounds are selected from the group consisting of metal nitrides, metal imides, metal amides, metal oxides, metal hydrides and metal sulfides.

27. A coated substrate as claimed in claim 21, wherein the metal is selected from the group consisting of group IIIB, group IVA, and group VIA of the Periodic Table of Elements.

28. A coated substrate as claimed In claim 21, wherein the metal is selected from the group consisting of Chrome (Cr), Titanium (Ti), Aluminium (Al) and Tantalum (Ta).

29. A coated substrate as claimed in claim 21, wherein the overall composition of at least one of the primary and secondary metal-gas compound layers are represented by the general formula:
MₓG_{y}
wherein,
M represents one or more metal atoms in the metal compound layer;
G represents one or more gas atoms meal compound layer;
x represents the fraction of metal atoms in the metal compound layer;
y represents the fraction of gas atoms in the metal compound layer; and
x+y=1.

30. A coated substrate as claimed in claim 29, wherein the value of y is selected from the group consisting of 0.08 to 0.35, 0.08 to 0.30, 0.08 to 0.25, 0.08 to 0.2, 0.08 to 0.18, 0.08 to 0.16, 0.08 to 0.15. 0.08 to 0.14, 0.08 to 0.13, 0.08 to 0.12, and 0.08 to 0.11.

31. A coated substrate as claimed in claim 29, wherein the value of x is selected from the group consisting of 0.92 to 0.65, 0.92 to 0.7, 0.92 to 0.75, 0.92 to 0.8, 0.92 to 0.82, 0.92 to 0.84, 0.92 to 0.85, 0.92 to 0.86, 0.92 to 0.87, 0.92 to 0.88 and 0.92 to 0.89.

32. A coated substrate as claimed in claim 29, wherein the metal-gas compound is selected from the group consisting of CrₓN_{y}; TiₓN_{y}; (TiAl)ₓN_{y}; TaₓN_{y}; and TiₓO_{y} and mixtures thereof.

33. A coated substrate as claimed in claim 21, wherein at least one of said primary and secondary metal-gas compound layers has a thickness in the range from 0.3 nm to 6 nm (3-60 angstroms).

34. A coated substrate as claimed in claim 21, wherein the metal-gas compound is chrome nitride.

35. A coated substrate as claimed in claim 34, wherein the nitrogen gas atom content in the primary layer of chrome nitride is selected from the group consisting of 8% to 35%, 8% to 30%, 9% to 20%, and 8% to 16% by atom number.

36. A coated substrate as claimed in claim 21, wherein said primary and said secondary metal-gas compound layers are formed by a Filtered Cathodic Vacuum Arc process.

37. A multi-coated substrate comprising:
a substrate;
a metal layer provided on the substrate; and
a plurality of metal-gas compound layers provided on said metal layer; at least two of said plurality of metal-gas compound layers having different gas atom contents.

38. A multi-coated substrate formed in a Filtered Cathodic Vacuum Arc process comprising:
a substrate;
a metal layer provided on the substrate; and
a plurality of metal-gas compound layers provided on said metal layer, at least two of said plurality of metal-gas compound layers having different gas atom contents.

39. A multi-coating for a substrate comprising:
a metal layer;
a primary metal-gas compound layer on said metal layer; and
a secondary metal-gas compound layer on said primary metal-gas compound layer, said secondary metal-gas compound layer having a different gas atom content relative to said first metal-gas compound layer.

40. A coating for a substrate comprising:
a metal layer;
a primary metal-gas compound layer on said metal layer; and
a secondary metal-gas compound layer on said primary metal-gas compound layer, said secondary metal-gas compound layer having a different gas atom content relative to said first metal-gas compound layer.

41. A coating as claimed in claim 40 comprising a plurality of metal layers alternating with, or interleaved with said metal-gas compound layers.

42. A substrate coated with a coating as claimed in claim 40.

43. A mould coated with a coating as claimed in claim 40.
